(19) United States
(12) Patent Application Publication
(10) Pub. No.: US 2024/0220675 A1
(43) Pub. Date: Jul. 4, 2024

(54) LIGHT RANGING AND DETECTION (LIDAR) BEAM DIVERGENCE SIMULATION

(71) Applicant: GM Cruise Holdings LLC, San Francisco, CA (US)

(72) Inventors: Amin Aghaei, Fremont, CA (US); Xin Jiang, San Jose, CA (US)

(21) Appl. No.: 18/092,804

(22) Filed: Jan. 3, 2023

(51) Int. Cl. G06F 30/20

(52) U.S. Cl. CPC G06F 30/20

(57) ABSTRACT

Systems and techniques are provided for simulating LiDAR sensors. An example method includes generating, within a simulation environment, at least one virtual beam transmission from a LiDAR sensor using a beam divergence model, wherein the at least one virtual beam transmission includes a plurality of rays; determining one or more intensity parameters associated with one or more virtual beam receptions by the LiDAR sensor, wherein the one or more virtual beam receptions correspond to one or more rays from the plurality of rays that are reflected from one or more virtual objects; adjusting the one or more intensity parameters based on one or more transmission intensity weights corresponding to the one or more rays to yield one or more modified intensity parameters; and determining at least one object intensity parameter for each of the one or more virtual objects based on the one or more modified intensity parameters.

### BACKGROUND

### 1. Technical Field

The present disclosure generally relates to autonomous vehicles and, more specifically, to simulating beam divergence for Light Detection and Ranging (LiDAR) sensors used by autonomous vehicles.

### 2. Introduction

Sensors are commonly integrated into a wide array of systems and electronic devices such as, for example, camera systems, mobile phones, autonomous systems (e.g., autonomous vehicles, unmanned aerial vehicles or drones, autonomous robots, etc.), computers, smart wearables, and many other devices. The sensors allow users to obtain sensor data that measures, describes, and/or depicts one or more aspects of a target such as an object, a scene, a person, and/or any other targets. For example, an image sensor can be used to capture frames (e.g., video frames and/or still pictures/images) depicting a target(s) from any electronic device equipped with an image sensor. As another example, a light detection and ranging (LiDAR) sensor can be used to determine ranges (variable distance) of one or more targets by directing a laser to a surface of an entity (e.g., a person, an object, a structure, an animal, etc.) and measuring the time for light reflected from the surface to return to the LiDAR.

### BRIEF DESCRIPTION OF THE DRAWINGS

The various advantages and features of the present technology will become apparent by reference to specific implementations illustrated in the appended drawings. A person of ordinary skill in the art will understand that these drawings only show some examples of the present technology and would not limit the scope of the present technology to these examples. Furthermore, the skilled artisan will appreciate the principles of the present technology as described and explained with additional specificity and detail through the use of the accompanying drawings in which:

FIG. 1 is a diagram illustrating an example system environment that can be used to facilitate autonomous vehicle (AV) navigation and routing operations, according to some examples of the present disclosure;

FIG. 2 is a diagram illustrating an example simulation framework, according to some examples of the present disclosure;

FIG. 3A is a diagram illustrating an example of a simulation framework for implementing a LiDAR beam divergence model, according to some examples of the present disclosure;

FIG. 3B is a diagram illustrating another example of a simulation framework for implementing a LiDAR beam divergence model, according to some examples of the present disclosure;

FIG. 4A is a diagram illustrating a cross-section view of a LiDAR beam for implementing a LiDAR beam divergence model, according to some examples of the present disclosure;

FIG. 4B is a diagram a portion of rays corresponding to a LiDAR beam for implementing a LiDAR beam divergence model, according to some examples of the present disclosure;

FIG. 5 is a diagram illustrating an example of a simulation framework for implementing a LiDAR noise model, according to some examples of the present disclosure;

FIG. 6 is a flow chart illustrating an example process for simulating LiDAR beam divergence, according to some examples of the present disclosure; and

FIG. 7 is a diagram illustrating an example system architecture for implementing certain aspects described herein, according to some examples of the present disclosure.

### DETAILED DESCRIPTION

The detailed description set forth below is intended as a description of various configurations of the subject technology and is not intended to represent the only configurations in which the subject technology can be practiced. The appended drawings are incorporated herein and constitute a part of the detailed description. The detailed description includes specific details for the purpose of providing a more thorough understanding of the subject technology. However, it will be clear and apparent that the subject technology is not limited to the specific details set forth herein and may be practiced without these details. In some instances, structures and components are shown in block diagram form in order to avoid obscuring the concepts of the subject technology.

One aspect of the present technology is the gathering and use of data available from various sources to improve quality and experience. The present disclosure contemplates that in some instances, this gathered data may include personal information. The present disclosure contemplates that the entities involved with such personal information respect and value privacy policies and practices.

Generally, sensors are integrated into a wide array of systems and electronic devices such as, for example, camera systems, mobile phones, autonomous systems (e.g., autonomous vehicles, unmanned aerial vehicles or drones, autonomous robots, etc.), computers, smart wearables, and many other devices. The sensors allow users to obtain sensor data that measures, describes, and/or depicts one or more aspects of a target such as an object, a scene, a person, and/or any other targets. For example, an image sensor can be used to capture frames (e.g., video frames and/or still pictures/images) depicting a target(s) from any electronic device equipped with an image sensor. As another example, a light detection and ranging (LiDAR) sensor can be used to determine ranges (variable distance) of one or more targets by directing a laser to a surface of an entity (e.g., a person, an object, a structure, an animal, etc.) and measuring the time of flight (e.g., time to receive reflection corresponding to LiDAR transmission).

In a LiDAR system, a LiDAR sensor emits light waves (laser signals) from a laser into the environment. The laser signals can reflect off the surface of surrounding objects and return to the LiDAR sensor. As a laser signal travels, beam divergence occurs which results in the increase in beam diameter or radius with distance from the optical aperture (e.g., laser source) from which the beam emerges. Consequently, as the laser travels further from its source the increase in beam diameter due to beam divergence may cause the laser to cover a wider area (e.g., larger beam spot). In some cases, a single beam may induce reflections from multiple objects because of beam divergence. However, while beam divergence may allow a LiDAR device to detect more objects (e.g., due to additional reflections), the intensity (e.g., energy) of the beam dissipates based on the divergence. That is, as the radius increases the corresponding energy decreases. Therefore, reflections induced based on beam divergence may be associated with reduced intensity. Moreover, as the laser travels further, the noise of range measurements increases due to the increase in the received pulse width that is caused by beam divergence.

Accurate simulation of LiDAR performance is critical to the development of autonomous vehicles. For example, software developers rely on simulations to configure modules such as the perception stack that relies on sensor data to detect and identify objects in the vicinity of the autonomous vehicle. In some cases, simulations of LiDAR sensors use a single ray to emulate a beam transmission. Consequently, the beam transmission is limited to a single return and the simulation does not accurately capture additional reflections that may occur in a real-world environment due to beam divergence. Additionally, a beam transmission that is limited to a single return fails to accurately simulate noise in range measurements that is caused by beam divergence. Furthermore, existing simulations that attempt to mimic beam divergence fail to account for energy dissipation that occurs in the radial direction as the beam travels further and its size increases.

Systems, apparatuses, processes (also referred to as methods), and computer-readable media (collectively referred to as “systems and techniques”) are described herein for simulating beam divergence of a LiDAR beam transmission. In some aspects, beam divergence of a LiDAR beam transmission can be simulated by using multiple rays that are configured around the center of the beam transmission. In some examples, the multiple rays can cause reflections from multiple objects in a simulation in a manner that is similar to a real-world environment in which a laser beam can hit multiple objects (e.g., one portion of the laser beam may hit a first object and another portion of the beam may hit a second object).

In some examples, a beam divergence model can be used to adjust the intensity parameters associated with multiple LiDAR returns corresponding to a single beam. For instance, a beam divergence model that is based on a gaussian distribution can be used to calculate weighted values for adjusting the intensity parameter associated with the multiple rays that are used to simulate beam divergence. Consequently, the simulation can accurately represent beam divergence in which returns corresponding to rays that are further from the beam center are associated with a lower intensity parameter.

In some aspects, a LiDAR noise model can be used to simulate variance or noise in range measurements that is caused by beam divergence. In some cases, the size of a beam spot (e.g., caused by beam divergence) can be determined based on parameters such as height of the LiDAR sensor, beam divergence angle, angle of incidence, and distance (e.g., range). In some examples, the size of the beam spot can be used to determine a minimum range measurement and a maximum range measurement which can correspond to photons that reflected from any point within the beam spot. In some instances, real-world noise can be modeled in the simulation environment by selecting a range value that is between the minimum range measurement and the maximum range measurement (e.g., based on a uniform distribution).

In some cases, the systems and techniques described herein can be used to accurately simulate LiDAR transmissions, LiDAR receptions, LiDAR beam divergence, and/or LiDAR measurement variability (e.g., range noise). In some examples, accurate simulation of LiDAR sensors can be used to optimize the performance of one or more machine learning models that utilize LiDAR data to detect and identify objects and/or to predict object movement. In one illustrative example, a simulation environment that accurately represents LiDAR sensor behavior can be used to develop and test AV software that uses LiDAR sensor data to operate the AV (e.g., perception stack, prediction stack, planning stack, etc. as described further herein).

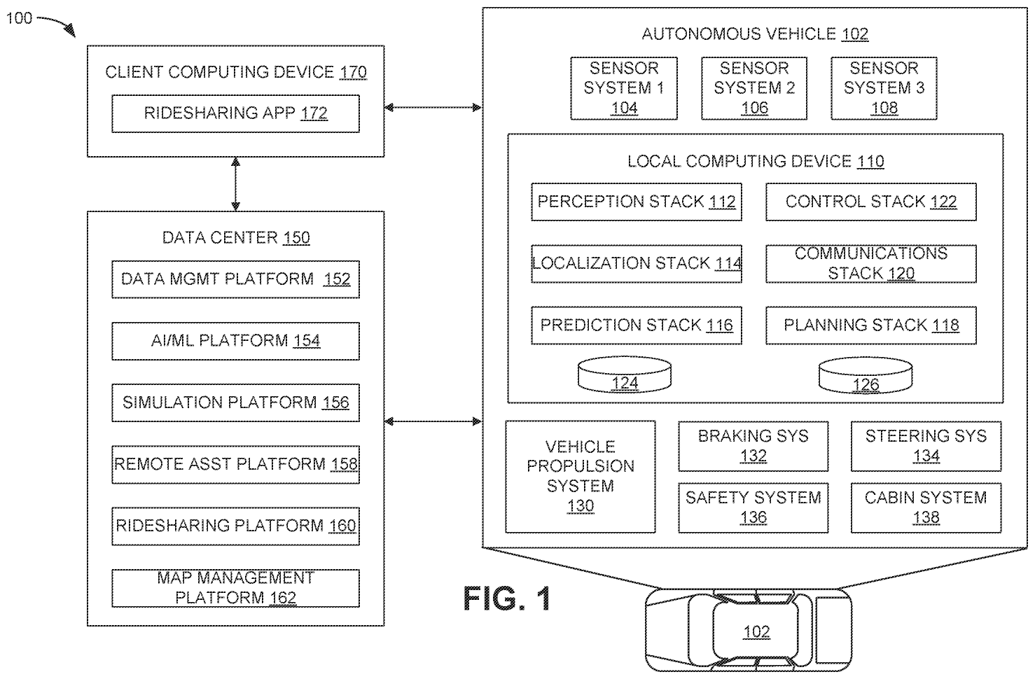

FIG. 1 is a diagram illustrating an example autonomous vehicle (AV) environment system 100, according to some examples of the present disclosure. One of ordinary skill in the art will understand that, for the AV environment system 100 and any system discussed in the present disclosure, there can be additional or fewer components in similar or alternative configurations. The illustrations and examples provided in the present disclosure are for conciseness and clarity. Other examples may include different numbers and/or types of elements, but one of ordinary skill the art will appreciate that such variations do not depart from the scope of the present disclosure.

In this example, the AV environment system 100 includes an AV 102, a data center 150, and a client computing device 170. The AV 102, the data center 150, and the client computing device 170 can communicate with one another over one or more networks (not shown), such as a public network (e.g., the Internet, an Infrastructure as a Service (IaaS) network, a Platform as a Service (PaaS) network, a Software as a Service (SaaS) network, other Cloud Service Provider (CSP) network, etc.), a private network (e.g., a Local Area Network (LAN), a private cloud, a Virtual Private Network (VPN), etc.), and/or a hybrid network (e.g., a multi-cloud or hybrid cloud network, etc.).

The AV 102 can navigate roadways without a human driver based on sensor signals generated by sensor systems 104, 106, and 108. The sensor systems 104-108 can include one or more types of sensors and can be arranged about the AV 102. For instance, the sensor systems 104-108 can include Inertial Measurement Units (IMUs), cameras (e.g., still image cameras, video cameras, etc.), light sensors (e.g., LiDAR systems, ambient light sensors, infrared sensors, etc.), RADAR systems, GPS receivers, audio sensors (e.g., microphones, Sound Navigation and Ranging (SONAR) systems, ultrasonic sensors, etc.), engine sensors, speedometers, tachometers, odometers, altimeters, tilt sensors, impact sensors, airbag sensors, seat occupancy sensors, open/closed door sensors, tire pressure sensors, rain sensors, and so forth. For example, the sensor system 104 can be a camera system, the sensor system 106 can be a LiDAR system, and the sensor system 108 can be a RADAR system. Other examples may include any other number and type of sensors.

The AV 102 can also include several mechanical systems that can be used to maneuver or operate the AV 102. For instance, the mechanical systems can include a vehicle propulsion system 130, a braking system 132, a steering system 134, a safety system 136, and a cabin system 138, among other systems. The vehicle propulsion system 130 can include an electric motor, an internal combustion engine, or both. The braking system 132 can include an engine brake, brake pads, actuators, and/or any other suitable componentry configured to assist in decelerating the AV 102. The steering system 134 can include suitable componentry configured to control the direction of movement of the AV 102 during navigation. The safety system 136 can include lights and signal indicators, a parking brake, airbags, and so forth. The cabin system 138 can include cabin temperature control systems, in-cabin entertainment systems, and so forth. In some examples, the AV 102 might not include human driver actuators (e.g., steering wheel, handbrake, foot brake pedal, foot accelerator pedal, turn signal lever, window wipers, etc.) for controlling the AV 102. Instead, the cabin system 138 can include one or more client interfaces (e.g., Graphical User Interfaces (GUIs), Voice User Interfaces (VUIs), etc.) for controlling certain aspects of the mechanical systems 130-138.

The AV 102 can include a local computing device 110 that is in communication with the sensor systems 104-108, the mechanical systems 130-138, the data center 150, and/or the client computing device 170, among other systems. The local computing device 110 can include one or more processors and memory, including instructions that can be executed by the one or more processors. The instructions can make up one or more software stacks or components responsible for controlling the AV 102; communicating with the data center 150, the client computing device 170, and other systems; receiving inputs from riders, passengers, and other entities within the AV's environment; logging metrics collected by the sensor systems 104-108; and so forth. In this example, the local computing device 110 includes a perception stack 112, a mapping and localization stack 114, a prediction stack 116, a planning stack 118, a communications stack 120, a control stack 122, an AV operational database 124, and an HD geospatial database 126, among other stacks and systems.

The perception stack 112 can enable the AV 102 to “see” (e.g., via cameras, LiDAR sensors, infrared sensors, etc.), “hear” (e.g., via microphones, ultrasonic sensors, RADAR, etc.), and “feel” (e.g., pressure sensors, force sensors, impact sensors, etc.) its environment using information from the sensor systems 104-108, the mapping and localization stack 114, the HD geospatial database 126, other components of the AV, and/or other data sources (e.g., the data center 150, the client computing device 170, third party data sources, etc.). The perception stack 112 can detect and classify objects and determine their current locations, speeds, directions, and the like. In addition, the perception stack 112 can determine the free space around the AV 102 (e.g., to maintain a safe distance from other objects, change lanes, park the AV, etc.). The perception stack 112 can identify environmental uncertainties, such as where to look for moving objects, flag areas that may be obscured or blocked from view, and so forth. In some examples, an output of the prediction stack can be a bounding area around a perceived object that can be associated with a semantic label that identifies the type of object that is within the bounding area, the kinematic of the object (information about its movement), a tracked path of the object, and a description of the pose of the object (its orientation or heading, etc.).

The mapping and localization stack 114 can determine the AV's position and orientation (pose) using different methods from multiple systems (e.g., GPS, IMUs, cameras, LiDAR, RADAR, ultrasonic sensors, the HD geospatial database 126, etc.). For example, in some cases, the AV 102 can compare sensor data captured in real-time by the sensor systems 104-108 to data in the HD geospatial database 126 to determine its precise (e.g., accurate to the order of a few centimeters or less) position and orientation. The AV 102 can focus its search based on sensor data from one or more first sensor systems (e.g., GPS) by matching sensor data from one or more second sensor systems (e.g., LiDAR). If the mapping and localization information from one system is unavailable, the AV 102 can use mapping and localization information from a redundant system and/or from remote data sources.

The prediction stack 116 can receive information from the localization stack 114 and objects identified by the perception stack 112 and predict a future path for the objects. In some examples, the prediction stack 116 can output several likely paths that an object is predicted to take along with a probability associated with each path. For each predicted path, the prediction stack 116 can also output a range of points along the path corresponding to a predicted location of the object along the path at future time intervals along with an expected error value for each of the points that indicates a probabilistic deviation from that point.

The planning stack 118 can determine how to maneuver or operate the AV 102 safely and efficiently in its environment. For example, the planning stack 118 can receive the location, speed, and direction of the AV 102, geospatial data, data regarding objects sharing the road with the AV 102 (e.g., pedestrians, bicycles, vehicles, ambulances, buses, cable cars, trains, traffic lights, lanes, road markings, etc.) or certain events occurring during a trip (e.g., emergency vehicle blaring a siren, intersections, occluded areas, street closures for construction or street repairs, double-parked cars, etc.), traffic rules and other safety standards or practices for the road, user input, and other relevant data for directing the AV 102 from one point to another and outputs from the perception stack 112, localization stack 114, and prediction stack 116. The planning stack 118 can determine multiple sets of one or more mechanical operations that the AV 102 can perform (e.g., go straight at a specified rate of acceleration, including maintaining the same speed or decelerating; turn on the left blinker, decelerate if the AV is above a threshold range for turning, and turn left; turn on the right blinker, accelerate if the AV is stopped or below the threshold range for turning, and turn right; decelerate until completely stopped and reverse; etc.), and select the best one to meet changing road conditions and events. If something unexpected happens, the planning stack 118 can select from multiple backup plans to carry out. For example, while preparing to change lanes to turn right at an intersection, another vehicle may aggressively cut into the destination lane, making the lane change unsafe. The planning stack 118 could have already determined an alternative plan for such an event. Upon its occurrence, it could help direct the AV 102 to go around the block instead of blocking a current lane while waiting for an opening to change lanes.

The control stack 122 can manage the operation of the vehicle propulsion system 130, the braking system 132, the steering system 134, the safety system 136, and the cabin system 138. The control stack 122 can receive sensor signals from the sensor systems 104-108 as well as communicate with other stacks or components of the local computing device 110 or a remote system (e.g., the data center 150) to effectuate operation of the AV 102. For example, the control stack 122 can implement the final path or actions from the multiple paths or actions provided by the planning stack 118. This can involve turning the routes and decisions from the planning stack 118 into commands for the actuators that control the AV's steering, throttle, brake, and drive unit.

The communications stack 120 can transmit and receive signals between the various stacks and other components of the AV 102 and between the AV 102, the data center 150, the client computing device 170, and other remote systems. The communications stack 120 can enable the local computing device 110 to exchange information remotely over a network, such as through an antenna array or interface that can provide a metropolitan WIFI network connection, a mobile or cellular network connection (e.g., Third Generation (3G), Fourth Generation (4G), Long-Term Evolution (LTE), 5th Generation (5G), etc.), and/or other wireless network connection (e.g., License Assisted Access (LAA), Citizens Broadband Radio Service (CBRS), MULTEFIRE, etc.). The communications stack 120 can also facilitate the local exchange of information, such as through a wired connection (e.g., a user's mobile computing device docked in an in-car docking station or connected via Universal Serial Bus (USB), etc.) or a local wireless connection (e.g., Wireless Local Area Network (WLAN), Bluetooth®, infrared, etc.).

The HD geospatial database 126 can store HD maps and related data of the streets upon which the AV 102 travels. In some examples, the HD maps and related data can comprise multiple layers, such as an areas layer, a lanes and boundaries layer, an intersections layer, a traffic controls layer, and so forth. The areas layer can include geospatial information indicating geographic areas that are drivable (e.g., roads, parking areas, shoulders, etc.) or not drivable (e.g., medians, sidewalks, buildings, etc.), drivable areas that constitute links or connections (e.g., drivable areas that form the same road) versus intersections (e.g., drivable areas where two or more roads intersect), and so on. The lanes and boundaries layer can include geospatial information of road lanes (e.g., lane centerline, lane boundaries, type of lane boundaries, etc.) and related attributes (e.g., direction of travel, speed limit, lane type, etc.). The lanes and boundaries layer can also include three-dimensional (3D) attributes related to lanes (e.g., slope, elevation, curvature, etc.). The intersections layer can include geospatial information of intersections (e.g., crosswalks, stop lines, turning lane centerlines and/or boundaries, etc.) and related attributes (e.g., permissive, protected/permissive, or protected only left turn lanes; legal or illegal u-turn lanes; permissive or protected only right turn lanes; etc.). The traffic controls lane can include geospatial information of traffic signal lights, traffic signs, and other road objects and related attributes.

The AV operational database 124 can store raw AV data generated by the sensor systems 104-108, stacks 112-122, and other components of the AV 102 and/or data received by the AV 102 from remote systems (e.g., the data center 150, the client computing device 170, etc.). In some examples, the raw AV data can include HD LiDAR point cloud data, image data, RADAR data, GPS data, and other sensor data that the data center 150 can use for creating or updating AV geospatial data or for creating simulations of situations encountered by AV 102 for future testing or training of various machine learning algorithms that are incorporated in the local computing device 110.

The data center 150 can include a private cloud (e.g., an enterprise network, a co-location provider network, etc.), a public cloud (e.g., an Infrastructure as a Service (IaaS) network, a Platform as a Service (PaaS) network, a Software as a Service (SaaS) network, or other Cloud Service Provider (CSP) network), a hybrid cloud, a multi-cloud, and/or any other network. The data center 150 can include one or more computing devices remote to the local computing device 110 for managing a fleet of AVs and AV-related services. For example, in addition to managing the AV 102, the data center 150 may also support a ridesharing service, a delivery service, a remote/roadside assistance service, street services (e.g., street mapping, street patrol, street cleaning, street metering, parking reservation, etc.), and the like.

The data center 150 can send and receive various signals to and from the AV 102 and the client computing device 170. These signals can include sensor data captured by the sensor systems 104-108, roadside assistance requests, software updates, ridesharing pick-up and drop-off instructions, and so forth. In this example, the data center 150 includes a data management platform 152, an Artificial Intelligence/Machine Learning (AI/ML) platform 154, a simulation platform 156, a remote assistance platform 158, and a ridesharing platform 160, and a map management platform 162, among other systems.

The data management platform 152 can be a “big data” system capable of receiving and transmitting data at high velocities (e.g., near real-time or real-time), processing a large variety of data and storing large volumes of data (e.g., terabytes, petabytes, or more of data). The varieties of data can include data having different structures (e.g., structured, semi-structured, unstructured, etc.), data of different types (e.g., sensor data, mechanical system data, ridesharing service, map data, audio, video, etc.), data associated with different types of data stores (e.g., relational databases, key-value stores, document databases, graph databases, column-family databases, data analytic stores, search engine databases, time series databases, object stores, file systems, etc.), data originating from different sources (e.g., AVs, enterprise systems, social networks, etc.), data having different rates of change (e.g., batch, streaming, etc.), and/or data having other characteristics. The various platforms and systems of the data center 150 can access data stored by the data management platform 152 to provide their respective services.

The AI/ML platform 154 can provide the infrastructure for training and evaluating machine learning algorithms for operating the AV 102, the simulation platform 156, the remote assistance platform 158, the ridesharing platform 160, the map management platform 162, and other platforms and systems. Using the AI/ML platform 154, data scientists can prepare data sets from the data management platform 152; select, design, and train machine learning models; evaluate, refine, and deploy the models; maintain, monitor, and retrain the models; and so on.

The simulation platform 156 can enable testing and validation of the algorithms, machine learning models, neural networks, and other development efforts for the AV 102, the remote assistance platform 158, the ridesharing platform 160, the map management platform 162, and other platforms and systems. The simulation platform 156 can replicate a variety of driving environments and/or reproduce real-world scenarios from data captured by the AV 102, including rendering geospatial information and road infrastructure (e.g., streets, lanes, crosswalks, traffic lights, stop signs, etc.) obtained from the map management platform 162 and/or a cartography platform; modeling the behavior of other vehicles, bicycles, pedestrians, and other dynamic elements; simulating inclement weather conditions, different traffic scenarios; and so on.

The remote assistance platform 158 can generate and transmit instructions regarding the operation of the AV 102. For example, in response to an output of the AI/ML platform 154 or other system of the data center 150, the remote assistance platform 158 can prepare instructions for one or more stacks or other components of the AV 102.

The ridesharing platform 160 can interact with a customer of a ridesharing service via a ridesharing application 172 executing on the client computing device 170. The client computing device 170 can be any type of computing system such as, for example and without limitation, a server, desktop computer, laptop computer, tablet computer, smartphone, smart wearable device (e.g., smartwatch, smart eyeglasses or other Head-Mounted Display (HMD), smart ear pods, or other smart in-ear, on-ear, or over-ear device, etc.), gaming system, or any other computing device for accessing the ridesharing application 172. In some cases, the client computing device 170 can be a customer's mobile computing device or a computing device integrated with the AV 102 (e.g., the local computing device 110). The ridesharing platform 160 can receive requests to pick up or drop off from the ridesharing application 172 and dispatch the AV 102 for the trip.

Map management platform 162 can provide a set of tools for the manipulation and management of geographic and spatial (geospatial) and related attribute data. The data management platform 152 can receive LiDAR point cloud data, image data (e.g., still image, video, etc.), RADAR data, GPS data, and other sensor data (e.g., raw data) from one or more AVs 102, Unmanned Aerial Vehicles (UAVs), satellites, third-party mapping services, and other sources of geospatially referenced data. The raw data can be processed, and map management platform 162 can render base representations (e.g., tiles (2D), bounding volumes (3D), etc.) of the AV geospatial data to enable users to view, query, label, edit, and otherwise interact with the data. Map management platform 162 can manage workflows and tasks for operating on the AV geospatial data. Map management platform 162 can control access to the AV geospatial data, including granting or limiting access to the AV geospatial data based on user-based, role-based, group-based, task-based, and other attribute-based access control mechanisms. Map management platform 162 can provide version control for the AV geospatial data, such as to track specific changes that (human or machine) map editors have made to the data and to revert changes when necessary. Map management platform 162 can administer release management of the AV geospatial data, including distributing suitable iterations of the data to different users, computing devices, AVs, and other consumers of HD maps. Map management platform 162 can provide analytics regarding the AV geospatial data and related data, such as to generate insights relating to the throughput and quality of mapping tasks.

In some examples, the map viewing services of map management platform 162 can be modularized and deployed as part of one or more of the platforms and systems of the data center 150. For example, the AI/ML platform 154 may incorporate the map viewing services for visualizing the effectiveness of various object detection or object classification models, the simulation platform 156 may incorporate the map viewing services for recreating and visualizing certain driving scenarios, the remote assistance platform 158 may incorporate the map viewing services for replaying traffic incidents to facilitate and coordinate aid, the ridesharing platform 160 may incorporate the map viewing services into the ridesharing application 172 to enable passengers to view the AV 102 in transit to a pick-up or drop-off location, and so on.

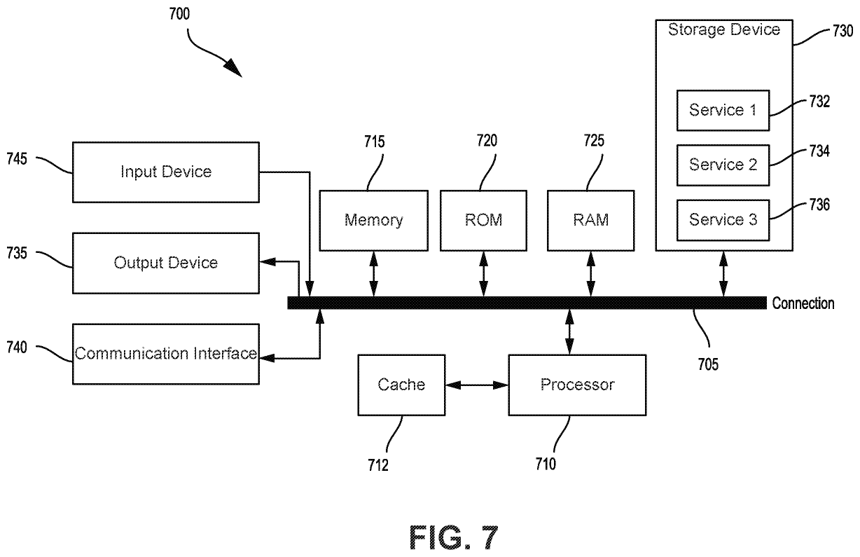

While the AV 102, the local computing device 110, and the AV environment system 100 are shown to include certain systems and components, one of ordinary skill will appreciate that the AV 102, the local computing device 110, and/or the AV environment system 100 can include more or fewer systems and/or components than those shown in FIG. 1. For example, the AV 102 can include other services than those shown in FIG. 1 and the local computing device 110 can also include, in some instances, one or more memory devices (e.g., RAM, ROM, cache, and/or the like), one or more network interfaces (e.g., wired and/or wireless communications interfaces and the like), and/or other hardware or processing devices that are not shown in FIG. 1. An illustrative example of a computing device and hardware components that can be implemented with the local computing device 110 is described below with respect to FIG. 7.

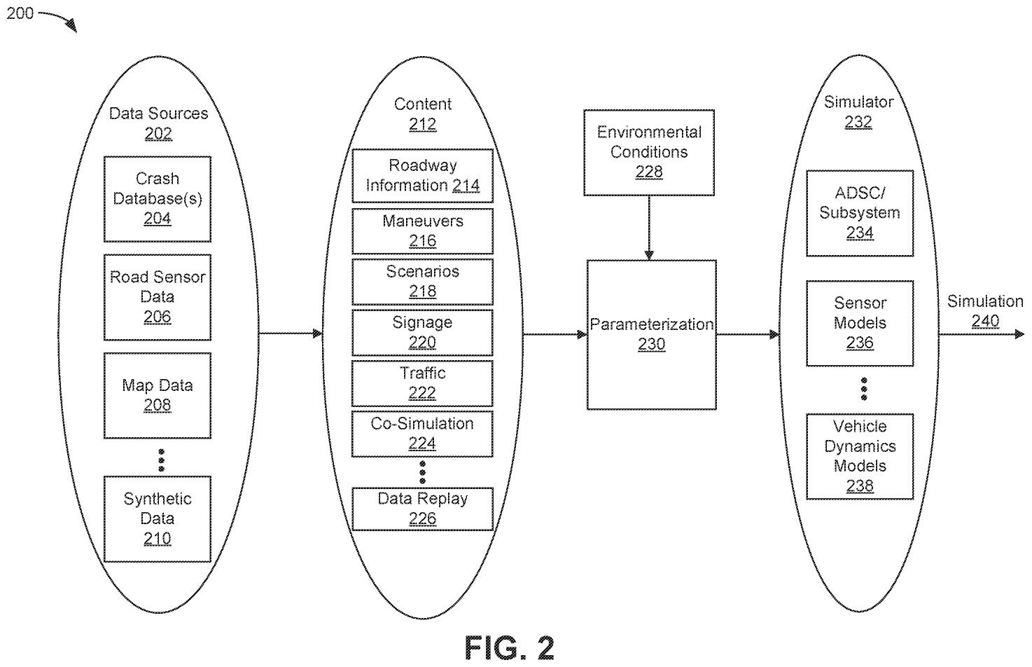

FIG. 2 is a diagram illustrating an example simulation framework 200, according to some examples of the present disclosure. The example simulation framework 200 can include data sources 202, content 212, environmental conditions 228, parameterization 230, and simulator 232. The components in the example simulation framework 200 are merely illustrative examples provided for explanation purposes. In other examples, the simulation framework 200 can include other components that are not shown in FIG. 2 and/or more or less components than shown in FIG. 2.

The data sources 202 can be used to create a simulation. The data sources 202 can include, for example and without limitation, one or more crash databases 204, road sensor data 206, map data 208, and/or synthetic data 210. In other examples, the data sources 202 can include more or less sources than shown in FIG. 2 and/or one or more data sources that are not shown in FIG. 2.

The crash databases 204 can include crash data (e.g., data describing crashes and/or associated details) generated by vehicles involved in crashes. The road sensor data 206 can include data collected by one or more sensors (e.g., one or more camera sensors, LiDAR sensors, RADAR sensors, SONAR sensors, IMU sensors, GPS/GNSS receivers, and/or any other sensors) of one or more vehicles while the one or more vehicles drive/navigate one or more real-world environments. The map data 208 can include one or more maps (and, in some cases, associated data) such as, for example and without limitation, one or more high-definition (HD) maps, sensor maps, scene maps, and/or any other maps. In some examples, the one or more HD maps can include roadway information such as, for example, lane widths, location of road signs and traffic lights, directions of travel for each lane, road junction information, speed limit information, etc.

The synthetic data 210 can include virtual assets, objects, and/or elements created for a simulated scene, a virtual scene and/or virtual scene elements, and/or any other synthetic data elements. For example, in some cases, the synthetic data 210 can include one or more virtual vehicles, virtual pedestrians, virtual roads, virtual objects, virtual environments/scenes, virtual signs, virtual backgrounds, virtual buildings, virtual trees, virtual motorcycles/bicycles, virtual obstacles, virtual environmental elements (e.g., weather, lightening, shadows, etc.), virtual surfaces, etc. In some aspects, the synthetic data 210 can include synthetic sensor data such as synthetic camera data, synthetic LiDAR data, synthetic RADAR data, synthetic IMU data, and/or any other type of synthetic sensor data.

In some examples, data from some or all of the data sources 202 can be used to create the content 212. The content 212 can include static content and/or dynamic content. For example, the content 212 can include roadway information 214, maneuvers 216, scenarios 218, signage 220, traffic 222, co-simulation 224, and/or data replay 226. The roadway information 214 can include, for example, lane information (e.g., number of lanes, lane widths, directions of travel for each lane, etc.), the location and information of road signs and/or traffic lights, road junction information, speed limit information, road attributes (e.g., surfaces, angles of inclination, curvatures, obstacles, etc.), road topologies, and/or other roadway information. The maneuvers 216 can include any AV maneuvers, and the scenarios 218 can include specific AV behaviors in certain AV scenes/environments. The signage 220 can include signs such as, for example, traffic lights, road signs, billboards, displayed messages on the road, etc. The traffic 222 can include any traffic information such as, for example, traffic density, traffic fluctuations, traffic patterns, traffic activity, delays, positions of traffic, velocities, volumes of vehicles in traffic, geometries or footprints of vehicles, pedestrians, spaces (occupied and/or unoccupied), etc.

The co-simulation 224 can include a distributed modeling and simulation of different AV subsystems that form the larger AV system. In some cases, the co-simulation 224 can include information for connecting separate simulations together with interactive communications. In some cases, the co-simulation 224 can allow for modeling to be done at a subsystem level while providing interfaces to connect the subsystems to the rest of the system (e.g., the autonomous driving system computer). Moreover, the data replay 226 can include replay content produced from real-world sensor data (e.g., road sensor data 206).

The environmental conditions 228 can include any information about environmental conditions 228. For example, the environmental conditions 228 can include atmospheric conditions, road/terrain conditions (e.g., surface slope or gradient, surface geometry, surface coefficient of friction, road obstacles, etc.), illumination, weather, road and/or scene conditions resulting from one or more environmental conditions, etc.

The content 212 and the environmental conditions 228 can be used to create the parameterization 230. The parameterization 230 can include parameter ranges, parameterized scenarios, probability density functions of one or more parameters, sampled parameter values, parameter spaces to be tested, evaluation windows for evaluating a behavior of an AV in a simulation, scene parameters, content parameters, environmental parameters, etc. The parameterization 230 can be used by a simulator 232 to generate a simulation 240.

The simulator 232 can include a software engine(s), algorithm(s), neural network model(s), and/or software component(s) used to generate simulations, such as simulation 240. In some examples, the simulator 232 can include autonomous driving system computer (ADSC)/subsystem models 234, sensor models 236, and a vehicle dynamics model 238. The ADSC/subsystem models 234 can include models, descriptors, and/or interfaces for the ADSC and/or ADSC subsystems such as, for example, a perception stack (e.g., perception stack 112), a localization stack (e.g., localization stack 114), a prediction stack (e.g., prediction stack 116), a planning stack (e.g., planning stack 118), a communications stack (e.g., communications stack 120), a control stack (e.g., control stack 122), a sensor system(s), and/or any other subsystems.

The sensor models 236 can include mathematical representations of hardware sensors and an operation (e.g., sensor data processing) of one or more sensors (e.g., a LiDAR, a RADAR, a SONAR, a camera sensor, an IMU, and/or any other sensor). For example, sensor models 236 can include a LiDAR sensor model that simulates operation of a LiDAR sensor. That is, a LIDAR sensor model can be used to simulate transmission of LiDAR beams in the simulation 240 and can simulate LiDAR measurements such as range, intensity, etc. corresponding to one or more objects in the simulation 240. The vehicle dynamics model 238 can model vehicle behaviors/operations, vehicle attributes, vehicle trajectories, vehicle positions, etc.

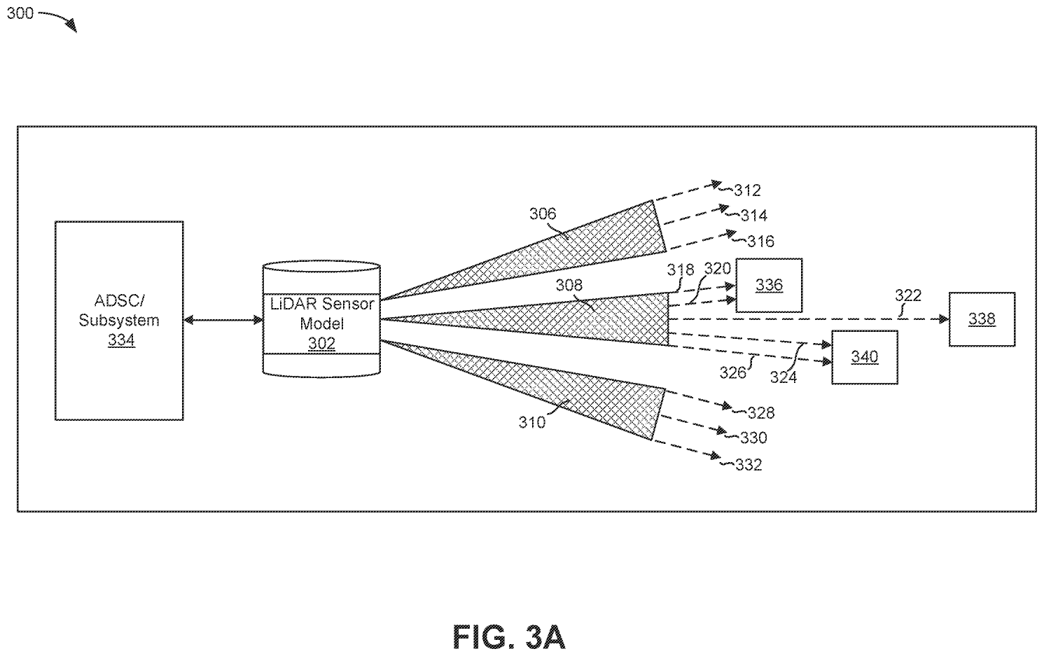

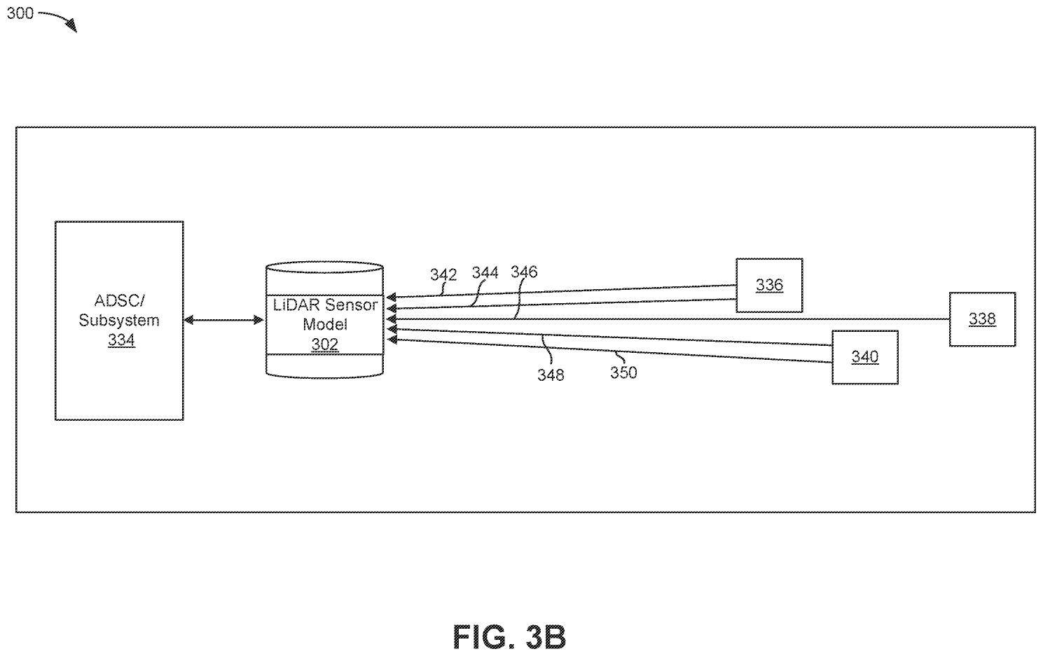

FIG. 3A is a diagram illustrating an example of a simulation environment 300 for implementing a LiDAR beam divergence model, according to some examples of the present disclosure. In some aspects, simulation environment 300 can include ADSC/Subsystem 334. In some cases, ADSC/Subsystem 334 may correspond to ADSC/Subsystem 234. As noted above, ADSC/Subsystem 334 may include a perception stack (e.g., perception stack 112), a localization stack (e.g., localization stack 114), a prediction stack (e.g., prediction stack 116), a planning stack (e.g., planning stack 118), a communications stack (e.g., communications stack 120), a control stack (e.g., control stack 122), a sensor system(s), and/or any other subsystems.

In some examples, simulation environment 300 can include LiDAR sensor model 302. In some instances, LiDAR sensor model 302 may be part of sensor models 236. In some cases, LiDAR sensor model 302 can be used to model or simulate the performance of a real-world LiDAR sensor. For instance, LiDAR sensor model 302 can be used to simulate a LiDAR sensor that is used by AV 102 as part of sensor system 104-108. In some aspects, LiDAR sensor model 302 may be used to simulate a rotating or spinning LiDAR sensor that is capable of capturing a 360-degree field of view. In some instances, LiDAR sensor model 302 may be used to simulate a LiDAR sensor that is fixed in place and is directed in a single direction with a limited field of view. In some examples, LiDAR sensor model 302 may be configured to provide LiDAR sensor data to ADSC/Subsystem 234. For example, LiDAR sensor model 302 may provide LiDAR sensor data to perception stack 112, and the perception stack 112 can use the LiDAR sensor data to detect and classify objects within simulation environment 300 (e.g., object 336, object 338, and/or object 340).

In some aspects, LiDAR sensor model 302 can generate one or more virtual beam transmissions. For example, LiDAR sensor model 302 can generate beam transmission 306, beam transmission 308, and/or beam transmission 310. In some cases, LiDAR sensor model 302 can generate beam transmissions (e.g., beam transmission 306, beam transmission 308, and/or beam transmission 310) that model beam divergence. That is, LiDAR sensor model 302 can be used to simulate the increase in beam diameter radius over distance. In some aspects, beam divergence may correspond to the angular measurement associated with the increase in beam diameter radius. In some instances, LiDAR sensor model 302 may also simulate a distribution of intensity (e.g., light energy) that is caused by beam divergence.

In some configurations, LiDAR sensor model 302 can model LiDAR beam divergence by including multiple rays within a single beam transmission. For example, beam transmission 306 can include ray 312, ray 314, and ray 316; beam transmission 308 can include ray 318, ray 320, ray 322, ray 324, and ray 326; and beam transmission 310 can include ray 328, ray 330, and ray 332. Those skilled in the art will recognize that the present technology is not limited to any particular number of rays per beam transmission and that different numbers of rays per beam transmission are contemplated herein.

In some aspects, modelling LiDAR beam divergence can emulate the performance of a real-world LiDAR sensor in which a single LiDAR beam transmission can detect multiple objects. For example, modelling LiDAR beam divergence can cause a single LiDAR beam transmission to produce hits or reflections from multiple objects. As illustrated in FIG. 3A, beam transmission 308 can be used to detect object 336 (e.g., using ray 318 and/or ray 320), object 338 (e.g., using ray 322) and object 340 (e.g., using ray 324 and/or ray 326).

FIG. 3B is a diagram illustrating another example of simulation environment 300 for implementing a LiDAR beam divergence model. In particular, FIG. 3B illustrates multiple beam receptions (e.g., beam reception 342, beam reception 344, beam reception 346, beam reception 348, and beam reception 350) that can be received by LiDAR sensor model 302. In some aspects, each of the beam receptions (e.g., beam reception 342 through beam reception 350) can correspond to a reflection of a ray (e.g., ray 318 through ray 326) that is associated with beam transmission 308. For example, beam reception 342 can correspond to a reflection of ray 318 from object 336; beam reception 344 can correspond to a reflection of ray 320 from object 336; beam reception 346 can correspond to a reflection of ray 322 from object 338; beam reception 348 can correspond to a reflection of ray 324 from object 340; and beam reception 350 can correspond to a reflection of ray 326 from object 340.

In some aspects, LiDAR sensor model 302 can determine one or more parameters associated with each beam reception (e.g., beam reception 342, beam reception 344, beam reception 346, beam reception 348, and beam reception 350). For example, LiDAR sensor model 302 can determine a range parameter (e.g., distance to an object) that is based on the time of flight of a LiDAR transmission (e.g., range or distance to object 338 can be based on time of flight of ray 322 which is based on beam reception 346).

In another example, LiDAR sensor model 302 can determine an intensity parameter that is associated with each ray (e.g., ray 318, ray 320, ray 322, ray 324, and ray 326) based on a corresponding beam reception (e.g., beam reception 342, beam reception 344, beam reception 346, beam reception 348, and beam reception 350). In some aspects, the intensity parameter can be a measure of the return signal strength of the laser pulse that generated the reflection. In some instances, the intensity parameter can correspond to a measurement of the transmitted power and/or the received power. In some cases, the intensity parameter can be based on the composition (e.g., reflectivity) of the surface object that caused the reflection (e.g., object 336, object 338, and/or object 340). For example, an object made with a retroreflective material can be associated with a relatively high reflectivity parameter and an object made with plastic can be associated with a relatively low reflectivity parameter. In some aspects, the reflectivity parameter corresponding to object 336, object 338, and/or object 340 may be determined or configured by the simulation framework (e.g., content 212 of simulation framework 200).

In some examples, the intensity parameter can be based on an angle of incidence formed between a ray and an object that caused the reflection (e.g., the angle between a ray incident on a surface and the line perpendicular to the surface at the point of incidence). For example, the incidence angle between ray 322 and object 338 (e.g., approximately 0 degrees) may result in a higher intensity parameter than an incidence angle that is greater than 0 degrees. In some instances, LiDAR sensor model 302 may determine the incidence angle based on the angle of arrival of a beam reception (e.g., beam reception 342, beam reception 344, beam reception 346, beam reception 348, and beam reception 350).

In some configurations, the intensity parameter can also be based on the range (e.g., distance to the reflecting object), the roughness of the reflecting object, and/or the moisture content. In some cases, the intensity parameter can be a dimensionless value. In some aspects, the intensity parameter can correspond to an integer value (e.g., a number between 1 and 256).

In some aspects, LiDAR sensor model 302 can modify the intensity parameter associated with each ray (e.g., ray 318, ray 320, ray 322, ray 324, and ray 326) based on a corresponding transmission intensity weight. In some aspects, the transmission intensity weight for a ray can be based on the position of the ray relative to the center of the beam transmission. That is, LiDAR sensor model 302 may use transmission intensity weights to simulate a distribution of intensity (e.g., light energy) that is caused by beam divergence.

In some examples, the intensity of a beam transmission can be based on a statistical distribution such as a gaussian distribution, a top-hat distribution, and/or any other type of distribution. In the case of a gaussian distribution, the intensity of a beam transmission can be determined according to Equation (1) below, in which r is the radial distance from the center axis of the beam; z is the axial distance from the beam's focus (or “waist”); E₀=F(0, 0) corresponds to the electric field amplitude (and phase) at the origin (r=0, z=0); w(z) is the radius at which the field amplitudes fall to 1/e of their axial values (e.g., where the intensity values fall to 1/e² of their axial values) at the plane z along the beam; and w₀=w(0) is the waist radius.

$$I ( r , z ) = \frac{{\vert E ( r , z ) \vert}^{2}}{2 n} = {{I}_{0} ( \frac{{ω}_{0}}{ω ( z )} )}^{2} exp ( \frac{- 2 {r}^{2}}{{ω ( z )}^{2}} ) \qquad ( 1 )$$

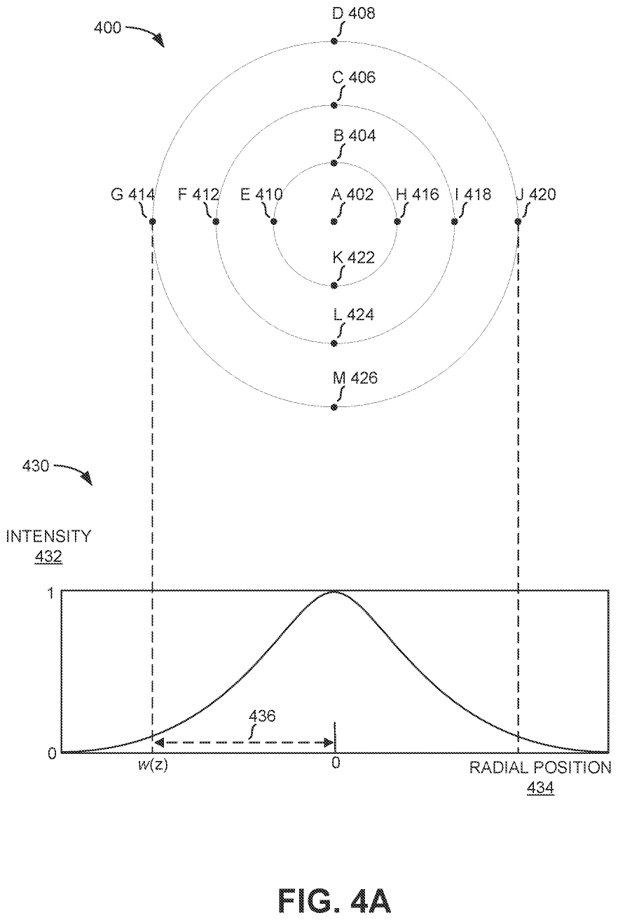

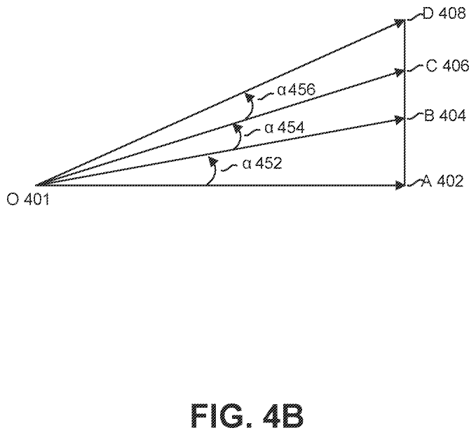

FIG. 4A illustrates a cross-section view of a LiDAR beam 400 for implementing a LiDAR beam divergence model. As illustrated, the beam spot of LiDAR beam 400 is a circle, but the beam spot may also be modeled using any shape such as a rectangle, oval, square, and/or any other type of irregular shape. FIG. 4A further illustrates an intensity plot 430 corresponding to a gaussian distribution of intensity based on the position of the rays relative to the center of the beam for LiDAR beam 400.

In some aspects, LiDAR beam 400 is modeled using center point A 402 that is surrounded by three concentric circles. Multiple points can be placed along the three concentric circles that correspond to rays that are used for modeling beam divergence. For example, point B 404, point E 410, point H 416, and point K 422 can correspond to rays along the innermost circle; point C 406, point F 412, point I 418, and point L 424 can correspond to rays along the intermediate circle; and point D 408, point G 414, point J 420, and point M 426 can correspond to rays along the outermost circle.

In some examples, the radius of the outermost circle can correspond to w(z) 436 (e.g., the radial position 434 at which the intensity 432 falls to 1/e² of the axial value). In some cases, this relationship can be expressed according to Equation (2), as follows:

$$\vert AD \vert = \vert AJ \vert = \vert AM \vert = \vert AG \vert = ω ( z ) \qquad ( 2 )$$

FIG. 4B is a diagram a portion of rays corresponding to a LiDAR beam for implementing a LiDAR beam divergence model. In particular, FIG. 4B illustrates the angle α 452 between a ray corresponding to point A 402 and a ray corresponding to point B 404 that originate at point O 401; the angle α 454 between a ray corresponding to point B 404 and a ray corresponding to point C 406 that originate at point O 401; and the angle α 456 between a ray corresponding to point C 406 and a ray corresponding to point D 408 that originate at point O 401.

In some cases, the angle α 452, the angle α 454, and the angle α 456 may be the same. In one illustrative example, a may be a relatively small value (e.g., a may be approximately 0.00053). Based on a small value of α, |AB|≈|BC|≈|CD|, and the intensity values can be determined according to the following equations:

$${I}_{B} = {I}_{A} \{ - \frac{2}{9} \} \approx 0.8 {I}_{A} \qquad ( 3 )$$

$${I}_{C} = {I}_{A} exp \{ - \frac{8}{9} \} \approx 0.4 \; 11 {I}_{A} \qquad ( 4 )$$

$${I}_{D} = {I}_{A} \{ - 2 \} \approx 0.1 \; 35 {I}_{A} \qquad ( 5 )$$

In some examples, the intensity values may be determined without making an approximation for the angle α (e.g., angle α 452, angle α 454, and angle α 456). For instance, the angle α can be used to determine the following equations:

$$\vert AB \vert = tan α \vert OA \vert \qquad ( 6 )$$

$$\vert AC \vert = tan 2 α \vert OA \vert \qquad ( 7 )$$

$$\vert AD \vert = tan 3 α \vert OA \vert \qquad ( 8 )$$

Based on equations (6) to (8), the intensity values can be determined as follows:

$${I}_{B} = {I}_{A} exp \{ - 2 ( \frac{tan α}{tan 3 α} ) \} \qquad ( 9 )$$

$${I}_{C} = {I}_{A} exp \{ - 2 ( \frac{tan 2 α}{tan 3 α} ) \} \qquad ( 10 )$$

$${I}_{D} = {I}_{A} exp \{ - 2 \} \approx 0.1 \; 35 {I}_{A} \qquad ( 11 )$$

In some aspects, the intensity at point B 404 can be equivalent to the intensity at point E 410, point H 416, and point K 422. In some examples, the intensity at point C 406 can be equivalent to the intensity at point F 412, point I 418, and point L 424. In some instances, the intensity at point D 408 can be equivalent to the intensity at point G 414, point J 420, and point M 426.

In some examples, the equations listed above can provide transmission intensity weights that can be used to adjust the intensity corresponding to one or more rays. For instance, the intensity value determined by the simulation (e.g., based on object reflectivity, angle of incidence, etc.) can be multiplied by the corresponding transmission intensity weight. In some aspects, the transmission intensity weights can be used to simulate a decrease in energy due to beam divergence. In some cases, the transmission energies for each of the rays can be normalized (e.g., sum of transmission intensity weights can be equal to 1).

Returning to FIG. 3B, in some aspects, LiDAR sensor model 302 may determine an intensity parameter for each object (e.g., object 336, object 338, and object 340). In some cases, the object intensity parameter may correspond to the strongest return. For instance, the object intensity parameter for object 336 may correspond to the intensity parameter associated with beam reception 342 or beam reception 344, whichever is higher. In some examples, the object intensity parameter may correspond to the range parameter associated with a return (e.g., longest return or shortest return). For example, the object intensity parameter for object 340 may correspond to the intensity parameter associated with beam reception 348 or beam reception 350 (e.g., whichever has a larger or a smaller range parameter).

In some aspects, the object intensity parameter may be a sum of all the intensity parameters associated with the object. For example, the object intensity parameter for object 336 may be the sum of the intensity parameter associated with beam reception 342 and the intensity parameter associated with beam reception 344. In another example, the object intensity parameter for object 340 may be the sum of the intensity parameter associated with beam reception 348 and the intensity parameter associated with beam reception 350.

In some cases, the beam receptions (e.g., returns) associated with an object may be discarded when the object intensity parameter is less than a threshold intensity value. For example, beam reception 342 and beam reception 344 may be discarded if the object intensity value for object 336 is less than a threshold intensity value. In one illustrative example, the threshold intensity value may be 1. That is, if the object intensity value for an object (e.g., the summed intensity values) is less than 1, the beam receptions associated with the object can be discarded. In some cases, LiDAR sensor model 302 can discard beam receptions by not reporting the data to ADSC/Subsystem 334 (e.g., the perception stack will not recognize an object because it does not receive LiDAR data corresponding to the object).

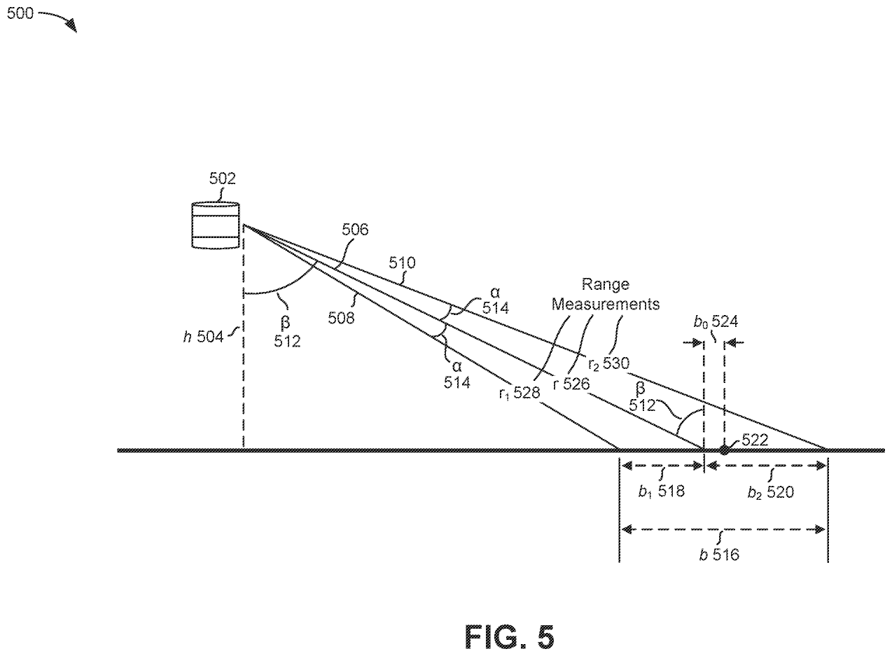

FIG. 5 is a diagram illustrating an example of a simulation framework 500 for implementing a LiDAR noise model. As noted above, beam divergence occurs as a laser signal travels through space, which results in an increase in beam diameter or radius as the distance from the laser source increases. In some cases, the noise (e.g., variation) that is associated with LiDAR range measurements also increases as the distance increases. In some instances, the increase in range noise can be due to beam divergence. In some aspects, the increase in range noise can be due to the size of the received pulse width, which is based on the angle of incidence. That is, the beam spot increases as the angle of incidence increases, which causes an increase in the pulse width that is received by the LiDAR sensor. In some configurations, a LiDAR noise model (as described in connection with FIG. 5) can be used to improve the accuracy of simulated LiDAR range measurements. In some aspects, a LiDAR noise model may be used together with or apart from a LiDAR beam divergence model.

In some examples, simulation framework 500 can be used to implement a LiDAR noise model that includes LiDAR sensor 502. In some aspects, a LiDAR noise model can be based on the height h 504 of LiDAR sensor 502, which can be configured to have any value. For instance, LiDAR sensor 502 may be positioned on the roof of an autonomous vehicle and height h 504 may have a value in the range of approximately 2 meters.

In some cases, a beam transmission from LiDAR sensor 502 can be associated with ray 506, ray 508, and ray 510. As illustrated, ray 506 corresponds to a center of the beam transmission (e.g., ray 506 can correspond to center point A 402). In some examples, the angle of incidence ß 512 can be measured from a vertical axis to the center of the beam transmission (e.g., to ray 506). In some aspects, ray 508 and ray 510 can correspond to rays that are located at or near the perimeter of the beam transmission. That is, ray 508 and ray 510 can diverge from ray 506 over distance based on the beam divergence half-angle α 514.

In some aspects, ray 506, ray 508, and ray 510 can each reflect from an object or surface. In some cases, ray 506, ray 508, and ray 510 can each return different range measurements (e.g., distance from LiDAR sensor 502 to surface or object). For example, ray 506 can be associated with range measurement r 526; ray 508 can be associated with range measurement r₁ 528; and ray 510 can be associated with range measurement r₂ 530. As illustrated in FIG. 5, ray 506, ray 508, and ray 510 reflect from a ground surface. However, those skilled in the art will recognize that the principles described herein for implementing a LiDAR noise model can be applied to beam transmissions in any direction that reflect from surfaces or objects irrespective of their position relative to LiDAR sensor 502.

In some examples, the beam transmission can generate a beam spot having a size (e.g., diameter) b 516. In some instances, the beam spot center 522 can be offset from ray 506 by a distance that can be defined as beam center offset b₀ 524. In some cases, beam spot size b 516 can be equivalent to the distance b₁ 518 from ray 506 to ray 508 plus the distance b₂ 520 from ray 506 to ray 510. In some aspect, b₀ (e.g., b₀ 524), b₁ (e.g., b₁ 518), and b₂ (e.g., b₂ 520) can be calculated based on height (e.g., h 504), beam divergence half-angle (e.g., α 514), and angle of incidence (e.g., β512), as follows:

$${b}_{1} = h [ tan β - tan ( β - α ) ] = r [ sin β - cos βtan ( β - α ) ] \qquad ( 12 )$$

$${b}_{2} = h [ tan ( β + α ) - tan β ] = r [ cos βtan ( β + α ) - sin β ] \qquad ( 13 )$$

$$b = {b}_{1} + {b}_{2} = r cos β [ tan ( β + α ) - tan ( β - α ) ] \qquad ( 14 )$$

$${b}_{o} = \frac{{b}_{2} - {b}_{1}}{2} \qquad ( 15 )$$

Table 1 below provides example values (e.g., calculated using equations (12) to (15) above) of the beam spot size b and the beam center offset b₀ for different given angles of incidence β. The examples in Table 1 are based on a beam divergence angle of 0.65 milli-radians and a height h of 2 meters for a range r of 50 meters.

TABLE 1

| Angle of incidence β (deg) | 0 | 30 | 60 | 75 | 85 | 87 |
|---|---|---|---|---|---|---|
| b (cm) | 6.5 | 7.5 | 13 | 25.1 | 74.6 | 124.2 |
| b₀ (cm) | 0 | 0.001 | 0.007 | 0.03 | 0.28 | 0.77 |

In some examples, LiDAR sensor 502 can receive photons from many points across a beam spot (e.g., within a beam spot having size b 516). In some aspects, the pulse width increases as the beam spot size increases. In some instances, beam divergence can cause range measurement noise such that a range measurement associated with beam spot of size b 516 will return a range value that has a minimum value corresponding to range measurement r₁ 528 and a maximum value corresponding to range measurement r₂ 530. In some aspects, r₁ (e.g., r₁ 528) and r₂ (e.g., r₂ 530) can be calculated as follows:

$${r}_{1} = r \frac{cos β}{cos ( β - α )} \qquad ( 16 )$$

$${r}_{2} = r \frac{cos β}{cos ( β + α )} \qquad ( 17 )$$

In some examples, simulation framework 500 can be used to calculate the minimum distance (e.g., r₁ 528) and the maximum distance (e.g., r₂ 530) for each point detected (e.g., for each LiDAR point). In some aspects, LiDAR range noise can be simulated by selecting a range value that is between the minimum distance and the maximum distance. In some instances, the range value can be selected randomly. In some configurations, the range value can be selected between the minimum distance and the maximum distance from a uniform distribution of values. In some aspects corresponding to LiDAR points from a ground surface (e.g., a road surface), the LiDAR noise model may calculate the minimum distance and the maximum distance based on a beam spreading angle (e.g., divergence half-angle α 514) that is approximately 0.2 milli-radians.

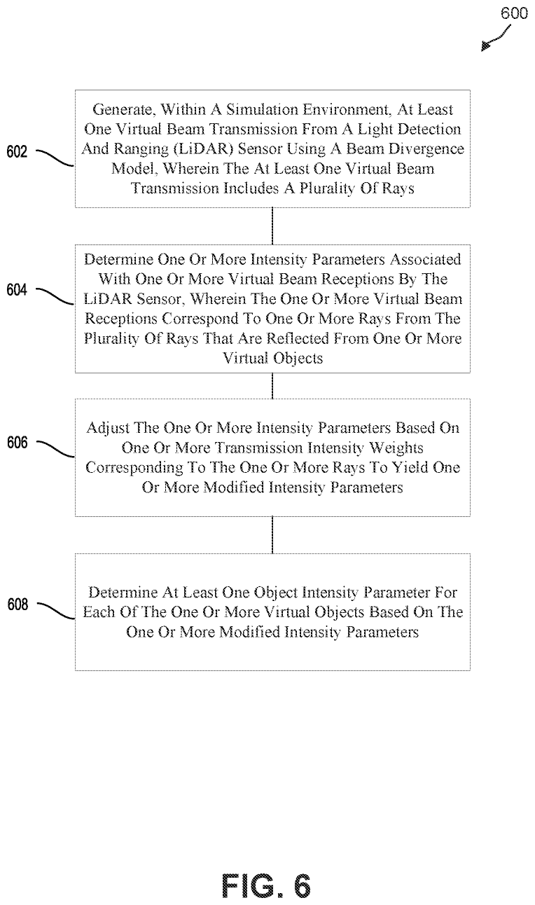

FIG. 6 illustrates a flowchart of an example process 600 for simulating LiDAR beam divergence. At step 602, the process 600 includes generating, within a simulation environment, at least one virtual beam transmission from a Light Detection and Ranging (LiDAR) sensor using a beam divergence model, wherein the at least one virtual beam transmission includes a plurality of rays. For example, LiDAR sensor model 302 can generate beam transmission 308 that includes ray 318, ray 320, ray 322, ray 324, and ray 326. In some cases, the beam divergence model can correspond to a gaussian beam divergence model (e.g., as illustrated and described in connection with FIG. 4A and FIG. 4B).

At step 604, the process 600 includes determining one or more intensity parameters associated with one or more virtual beam receptions by the LiDAR sensor, wherein the one or more virtual beam receptions correspond to one or more rays from the plurality of rays that are reflected from one or more virtual objects. For instance, LiDAR sensor model 302 can determine an intensity parameter associated with beam reception 342, which corresponds to ray 318 reflected from object 336. In some examples, the one or more intensity parameters can be based on an angle of incidence between a corresponding ray from the one or more rays and a corresponding virtual object from the one or more virtual objects. For instance, the intensity parameter corresponding to beam reception 342 can be based on an incidence angle between ray 318 and object 336. In some cases, the one or more intensity parameters can be based on one or more reflectivity parameters corresponding to the one or more virtual objects. For example, the intensity parameter corresponding to beam reception 346 can be based on a reflectivity parameter corresponding to object 338. In some configurations, the reflectivity parameter is configured by the simulation framework (e.g., each virtual object has a corresponding reflectivity parameter).

At step 606, the process 600 includes adjusting the one or more intensity parameters based on one or more transmission intensity weights corresponding to the one or more rays to yield one or more modified intensity parameters. For example, LiDAR sensor model 302 can adjust the intensity parameter associated with beam reception 342 using a gaussian intensity distribution as illustrated in FIG. 4A. In some cases, the transmission intensity weight can be based on the position of the ray relative to the center of the beam transmission (e.g., rays that are further from the center will have a transmission intensity weight that results in a lower intensity). In some aspects, the one or more transmission intensity weights can be based on a distance of each of the plurality of rays from a center of the at least one virtual beam transmission. For example, the intensity of a ray corresponding to point G 414 is based on a radius from center point A 402.

At step 608, the process 600 includes determining at least one object intensity parameter for each of the one or more virtual objects based on the one or more modified intensity parameters. For example, LiDAR sensor model 302 can determine an object intensity parameter for object 336, object 338, and/or object 340. In some aspects, the object intensity parameter for object 336 can be based on a sum of the modified (e.g., weighted) intensity parameters associated with beam reception 342 and beam reception 344.

In some cases, the process 600 can include determining that the at least one object intensity parameter corresponding to a first virtual object from the one or more virtual objects is less than a threshold intensity value and disregarding a portion of virtual beam receptions from the one or more virtual beam receptions, wherein the portion of virtual beam receptions corresponds to reflections of the one or more rays from the first virtual object. For example, LiDAR sensor model 302 can determine that the object intensity parameter associated with object 340 is less than a threshold intensity value and LiDAR sensor model 302 can disregard beam reception 348 and beam reception 350.

In some examples, the process 600 can include sending the one or more modified intensity parameters to a perception stack of an autonomous vehicle operating in the simulation environment. For example, LiDAR sensor model 302 can send the one or more modified intensity parameters to a perception stack (e.g., perception stack 112) within ADSC/Subsystem 334.

FIG. 7 illustrates an example processor-based system with which some aspects of the subject technology can be implemented. For example, processor-based system 700 can be any computing device making up local computing device 110, client computing device 170, a passenger device executing the ridesharing application 172, or any component thereof in which the components of the system are in communication with each other using connection 705. Connection 705 can be a physical connection via a bus, or a direct connection into processor 710, such as in a chipset architecture. Connection 705 can also be a virtual connection, networked connection, or logical connection.

In some examples, computing system 700 is a distributed system in which the functions described in this disclosure can be distributed within a datacenter, multiple data centers, a peer network, etc. In some cases, one or more of the described system components represents many such components each performing some or all of the function for which the component is described. In some cases, the components can be physical or virtual devices.

Example system 700 includes at least one processing unit (CPU or processor) 710 and connection 705 that couples various system components including system memory 715, such as read-only memory (ROM) 720 and random-access memory (RAM) 725 to processor 710. Computing system 700 can include a cache of high-speed memory 712 connected directly with, in close proximity to, and/or integrated as part of processor 710.

Processor 710 can include any general-purpose processor and a hardware service or software service, such as services 732, 734, and 736 stored in storage device 730, configured to control processor 710 as well as a special-purpose processor where software instructions are incorporated into the actual processor design. Processor 710 may essentially be a completely self-contained computing system, containing multiple cores or processors, a bus, memory controller, cache, etc. A multi-core processor may be symmetric or asymmetric.

To enable user interaction, computing system 700 can include an input device 745, which can represent any number of input mechanisms, such as a microphone for speech, a touch-sensitive screen for gesture or graphical input, keyboard, mouse, motion input, speech, etc. Computing system 700 can also include output device 735, which can be one or more of a number of output mechanisms known to those of skill in the art. In some instances, multimodal systems can enable a user to provide multiple types of input/output to communicate with computing system 700. Computing system 700 can include communications interface 740, which can generally govern and manage the user input and system output. The communication interface may perform or facilitate receipt and/or transmission wired or wireless communications via wired and/or wireless transceivers, including those making use of an audio jack/plug, a microphone jack/plug, a universal serial bus (USB) port/plug, an Apple® Lightning® port/plug, an Ethernet port/plug, a fiber optic port/plug, a proprietary wired port/plug, a BLUETOOTH® wireless signal transfer, a BLUETOOTH® low energy (BLE) wireless signal transfer, an IBEACON® wireless signal transfer, a radio-frequency identification (RFID) wireless signal transfer, near-field communications (NFC) wireless signal transfer, dedicated short range communication (DSRC) wireless signal transfer, 802.11 Wi-Fi wireless signal transfer, wireless local area network (WLAN) signal transfer, Visible Light Communication (VLC), Worldwide Interoperability for Microwave Access (WiMAX), Infrared (IR) communication wireless signal transfer, Public Switched Telephone Network (PSTN) signal transfer, Integrated Services Digital Network (ISDN) signal transfer, 3G/4G/9G/LTE cellular data network wireless signal transfer, ad-hoc network signal transfer, radio wave signal transfer, microwave signal transfer, infrared signal transfer, visible light signal transfer, ultraviolet light signal transfer, wireless signal transfer along the electromagnetic spectrum, or some combination thereof.

Communications interface 740 may also include one or more Global Navigation Satellite System (GNSS) receivers or transceivers that are used to determine a location of the computing system 700 based on receipt of one or more signals from one or more satellites associated with one or more GNSS systems. GNSS systems include, but are not limited to, the US-based Global Positioning System (GPS), the Russia-based Global Navigation Satellite System (GLONASS), the China-based BeiDou Navigation Satellite System (BDS), and the Europe-based Galileo GNSS. There is no restriction on operating on any particular hardware arrangement, and therefore the basic features here may easily be substituted for improved hardware or firmware arrangements as they are developed.

Storage device 730 can be a non-volatile and/or non-transitory computer-readable memory device and can be a hard disk or other types of computer readable media which can store data that are accessible by a computer, such as magnetic cassettes, flash memory cards, solid state memory devices, digital versatile disks, cartridges, a floppy disk, a flexible disk, a hard disk, magnetic tape, a magnetic strip/stripe, any other magnetic storage medium, flash memory, memristor memory, any other solid-state memory, a compact disc read only memory (CD-ROM) optical disc, a rewritable compact disc (CD) optical disc, digital video disk (DVD) optical disc, a blu-ray disc (BDD) optical disc, a holographic optical disk, another optical medium, a secure digital (SD) card, a micro secure digital (microSD) card, a Memory Stick® card, a smartcard chip, a EMV chip, a subscriber identity module (SIM) card, a mini/micro/nano/pico SIM card, another integrated circuit (IC) chip/card, random access memory (RAM), static RAM (SRAM), dynamic RAM (DRAM), read-only memory (ROM), programmable read-only memory (PROM), erasable programmable read-only memory (EPROM), electrically erasable programmable read-only memory (EEPROM), flash EPROM (FLASHEPROM), cache memory (L1/L2/L3/L4/L9/L #), resistive random-access memory (RRAM/ReRAM), phase change memory (PCM), spin transfer torque RAM (STT-RAM), another memory chip or cartridge, and/or a combination thereof.

Storage device 730 can include software services, servers, services, etc., that when the code that defines such software is executed by the processor 710, causes the system to perform a function. In some examples, a hardware service that performs a particular function can include the software component stored in a computer-readable medium in connection with the necessary hardware components, such as processor 710, connection 705, output device 735, etc., to carry out the function.

Aspects within the scope of the present disclosure may also include tangible and/or non-transitory computer-readable storage media or devices for carrying or having computer-executable instructions or data structures stored thereon. Such tangible computer-readable storage devices can be any available device that can be accessed by a general purpose or special purpose computer, including the functional design of any special purpose processor as described above. By way of example, and not limitation, such tangible computer-readable devices can include RAM, ROM, EEPROM, CD-ROM or other optical disk storage, magnetic disk storage or other magnetic storage devices, or any other device which can be used to carry or store desired program code in the form of computer-executable instructions, data structures, or processor chip design. When information or instructions are provided via a network or another communications connection (either hardwired, wireless, or combination thereof) to a computer, the computer properly views the connection as a computer-readable medium. Thus, any such connection is properly termed a computer-readable medium. Combinations of the above should also be included within the scope of the computer-readable storage devices.

Computer-executable instructions include, for example, instructions and data which cause a general-purpose computer, special-purpose computer, or special-purpose processing device to perform a certain function or group of functions. By way of example, computer-executable instructions can be used to implement perception system functionality for determining when sensor cleaning operations are needed or should begin. Computer-executable instructions can also include program modules that are executed by computers in stand-alone or network environments. Generally, program modules include routines, programs, components, data structures, objects, and the functions inherent in the design of special-purpose processors, etc. that perform tasks or implement abstract data types. Computer-executable instructions, associated data structures, and program modules represent examples of the program code means for executing steps of the methods disclosed herein. The particular sequence of such executable instructions or associated data structures represents examples of corresponding acts for implementing the functions described in such steps.

Other examples of the disclosure may be practiced in network computing environments with many types of computer system configurations, including personal computers, hand-held devices, multi-processor systems, microprocessor-based or programmable consumer electronics, network PCs, minicomputers, mainframe computers, and the like. Aspects of the disclosure may also be practiced in distributed computing environments where tasks are performed by local and remote processing devices that are linked (either by hardwired links, wireless links, or by a combination thereof) through a communications network. In a distributed computing environment, program modules can be located in both local and remote memory storage devices.

The various examples described above are provided by way of illustration only and should not be construed to limit the scope of the disclosure. For example, the principles herein apply equally to optimization as well as general improvements. Various modifications and changes may be made to the principles described herein without following the example aspects and applications illustrated and described herein, and without departing from the spirit and scope of the disclosure.

Claim language or other language in the disclosure reciting “at least one of” a set and/or “one or more” of a set indicates that one member of the set or multiple members of the set (in any combination) satisfy the claim. For example, claim language reciting “at least one of A and B” or “at least one of A or B” means A, B, or A and B. In another example, claim language reciting “at least one of A, B, and C” or “at least one of A, B, or C” means A, B, C, or A and B, or A and C, or B and C, or A and B and C. The language “at least one of” a set and/or “one or more” of a set does not limit the set to the items listed in the set. For example, claim language reciting “at least one of A and B” or “at least one of A or B” can mean A, B, or A and B, and can additionally include items not listed in the set of A and B.

Illustrative examples of the disclosure include:

Aspect 1. A method comprising: generating, within a simulation environment, at least one virtual beam transmission from a Light Detection and Ranging (LiDAR) sensor using a beam divergence model, wherein the at least one virtual beam transmission includes a plurality of rays; determining one or more intensity parameters associated with one or more virtual beam receptions by the LiDAR sensor, wherein the one or more virtual beam receptions correspond to one or more rays from the plurality of rays that are reflected from one or more virtual objects; adjusting the one or more intensity parameters based on one or more transmission intensity weights corresponding to the one or more rays to yield one or more modified intensity parameters; and determining at least one object intensity parameter for each of the one or more virtual objects based on the one or more modified intensity parameters.

Aspect 2. The method of Aspect 1, further comprising: determining that the at least one object intensity parameter corresponding to a first virtual object from the one or more virtual objects is less than a threshold intensity value; and disregarding a portion of virtual beam receptions from the one or more virtual beam receptions, wherein the portion of virtual beam receptions corresponds to reflections of the one or more rays from the first virtual object.

Aspect 3. The method of any of Aspects 1 to 2, wherein the beam divergence model corresponds to a gaussian beam divergence model.

Aspect 4. The method of any of Aspects 1 to 3, wherein the one or more intensity parameters are based on an angle of incidence between a corresponding ray from the one or more rays and a corresponding virtual object from the one or more virtual objects.

Aspect 5. The method of any of Aspects 1 to 4, wherein the one or more intensity parameters are based on one or more reflectivity parameters corresponding to the one or more virtual objects.

Aspect 6. The method of any of Aspects 1 to 5, wherein the one or more transmission intensity weights are based on a distance of each of the plurality of rays from a center of the at least one virtual beam transmission.

Aspect 7. The method of any of Aspects 1 to 6, further comprising: sending the one or more modified intensity parameters to a perception stack of an autonomous vehicle operating in the simulation environment.

Aspect 8. An apparatus comprising: at least one memory; and at least one processor coupled to the at least one memory, wherein the at least one processor is configured to perform operations in accordance with any one of Aspects 1 to 7.

Aspect 9. An apparatus comprising means for performing operations in accordance with any one of Aspects 1 to 7.

Aspect 10. A non-transitory computer-readable medium comprising instructions that, when executed by an apparatus, cause the apparatus to perform operations in accordance with any one of Aspects 1 to 7.

What is claimed is:

1. A system comprising:
a memory; and
one or more processors coupled to the memory, the one or more processors being configured to:
generate, within a simulation environment, at least one virtual beam transmission from a Light Detection and Ranging (LiDAR) sensor using a beam divergence model, wherein the at least one virtual beam transmission includes a plurality of rays;
determine one or more intensity parameters associated with one or more virtual beam receptions by the LiDAR sensor, wherein the one or more virtual beam receptions correspond to one or more rays from the plurality of rays that are reflected from one or more virtual objects;
adjust the one or more intensity parameters based on one or more transmission intensity weights corresponding to the one or more rays to yield one or more modified intensity parameters; and
determine at least one object intensity parameter for each of the one or more virtual objects based on the one or more modified intensity parameters.

2. The system of claim 1, wherein the one or more processors are further configured to:
determine that the at least one object intensity parameter corresponding to a first virtual object from the one or more virtual objects is less than a threshold intensity value; and
disregard a portion of virtual beam receptions from the one or more virtual beam receptions, wherein the portion of virtual beam receptions corresponds to reflections of the one or more rays from the first virtual object.

3. The system of claim 1, wherein the beam divergence model corresponds to a gaussian beam divergence model.

4. The system of claim 1, wherein the one or more intensity parameters are based on an angle of incidence between a corresponding ray from the one or more rays and a corresponding virtual object from the one or more virtual objects.

5. The system of claim 1, wherein the one or more intensity parameters are based on one or more reflectivity parameters corresponding to the one or more virtual objects.

6. The system of claim 1, wherein the one or more transmission intensity weights are based on a distance of each of the plurality of rays from a center of the at least one virtual beam transmission.

7. The system of claim 1, wherein the one or more processors are further configured to:
send the one or more modified intensity parameters to a perception stack of an autonomous vehicle operating in the simulation environment.

8. A method comprising:
generating, within a simulation environment, at least one virtual beam transmission from a Light Detection and Ranging (LiDAR) sensor using a beam divergence model, wherein the at least one virtual beam transmission includes a plurality of rays;
determining one or more intensity parameters associated with one or more virtual beam receptions by the LiDAR sensor, wherein the one or more virtual beam receptions correspond to one or more rays from the plurality of rays that are reflected from one or more virtual objects;
adjusting the one or more intensity parameters based on one or more transmission intensity weights corresponding to the one or more rays to yield one or more modified intensity parameters; and
determining at least one object intensity parameter for each of the one or more virtual objects based on the one or more modified intensity parameters.

9. The method of claim 8, further comprising:
determining that the at least one object intensity parameter corresponding to a first virtual object from the one or more virtual objects is less than a threshold intensity value; and
disregarding a portion of virtual beam receptions from the one or more virtual beam receptions, wherein the portion of virtual beam receptions corresponds to reflections of the one or more rays from the first virtual object.

10. The method of claim 8, wherein the beam divergence model corresponds to a gaussian beam divergence model.

11. The method of claim 8, wherein the one or more intensity parameters are based on an angle of incidence between a corresponding ray from the one or more rays and a corresponding virtual object from the one or more virtual objects.

12. The method of claim 8, wherein the one or more intensity parameters are based on one or more reflectivity parameters corresponding to the one or more virtual objects.

13. The method of claim 8, wherein the one or more transmission intensity weights are based on a distance of each of the plurality of rays from a center of the at least one virtual beam transmission.

14. The method of claim 8, further comprising:
sending the one or more modified intensity parameters to a perception stack of an autonomous vehicle operating in the simulation environment.

15. A non-transitory computer-readable media comprising instructions stored thereon which, when executed are configured to cause a computer or processor to:
generate, within a simulation environment, at least one virtual beam transmission from a Light Detection and Ranging (LiDAR) sensor using a beam divergence model, wherein the at least one virtual beam transmission includes a plurality of rays;
determine one or more intensity parameters associated with one or more virtual beam receptions by the LiDAR sensor, wherein the one or more virtual beam receptions correspond to one or more rays from the plurality of rays that are reflected from one or more virtual objects;
adjust the one or more intensity parameters based on one or more transmission intensity weights corresponding to the one or more rays to yield one or more modified intensity parameters; and
determine at least one object intensity parameter for each of the one or more virtual objects based on the one or more modified intensity parameters.

16. The non-transitory computer-readable media of claim 15, comprising further instructions configured to cause the computer or the processor to:
determine that the at least one object intensity parameter corresponding to a first virtual object from the one or more virtual objects is less than a threshold intensity value; and
disregard a portion of virtual beam receptions from the one or more virtual beam receptions, wherein the portion of virtual beam receptions corresponds to reflections of the one or more rays from the first virtual object.

17. The non-transitory computer-readable media of claim 15, wherein the one or more intensity parameters are based on an angle of incidence between a corresponding ray from the one or more rays and a corresponding virtual object from the one or more virtual objects.

18. The non-transitory computer-readable media of claim 15, wherein the one or more intensity parameters are based on one or more reflectivity parameters corresponding to the one or more virtual objects.

19. The non-transitory computer-readable media of claim 15, wherein the one or more transmission intensity weights are based on a distance of each of the plurality of rays from a center of the at least one virtual beam transmission.

20. The non-transitory computer-readable media of claim 15, comprising further instructions configured to cause the computer or the processor to:
send the one or more modified intensity parameters to a perception stack of an autonomous vehicle operating in the simulation environment.
